(19) United States
(12) Patent Application Publication
(10) Pub. No.: US 2003/0089973 A1
(43) Pub. Date: May 15, 2003

(54) Semiconductor device and method of manufacturing the same, circuit board, and electronic equipment

(75) Inventor: Hideo Miyasaka, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/269,942

(22) Filed: Oct. 15, 2002

(30) Foreign Application Priority Data
Nov. 9, 2001 (JP) 2001-344176

(51) Int. Cl. H01L 23/48

(52) U.S. Cl. 257/688

(57) ABSTRACT

A manufacturing method of a semiconductor device comprising pressing a semiconductor chip having a first surface on which electrodes are formed to a substrate having an interconnecting pattern with an adhesive which is located between the first surface and the substrate, and connecting the electrodes to the interconnecting pattern electrically, and forming an adhesive section which is made of the adhesive on a side surface of the semiconductor chip, and grinding the semiconductor chip and the adhesive section simultaneously from a second surface of the semiconductor chip opposite to the first surface.

Japanese Patent Application No. 2001-344176 filed on Nov. 9, 2001, is hereby incorporated by reference in its entirety.

### BACKGROUND OF THE INVENTION

The present invention relates to a semiconductor device and a method of manufacturing the same, a circuit board, and electronic equipment.

It is known in the art that a semiconductor chip is thinly ground in order to achieve a decrease in size and an increase in the degree of integration of a semiconductor device. The semiconductor chip is ground on the side (active surface) opposite to the side on which a circuit element is formed. The thinly ground semiconductor chip is mounted on a substrate.

However, since the thinly ground semiconductor chip easily cracks, it may crack in manufacturing steps before mounting the semiconductor chip on the substrate. The semiconductor chip may be warped when bonding to the substrate due to force applied by a bonding tool.

### BRIEF SUMMARY OF THE INVENTION

According to the first aspect of the present invention, a manufacturing method of a semiconductor device comprises:

(a) pressing a semiconductor chip having a first surface on which electrodes are formed to a substrate having an interconnecting pattern with an adhesive which is located between the first surface and the substrate, and connecting the electrodes to the interconnecting pattern electrically, and forming an adhesive section which is made of the adhesive on a side surface of the semiconductor chip; and

(b) grinding the semiconductor chip and the adhesive section simultaneously from a second surface of the semiconductor chip opposite to the first surface.

According to the second aspect of the present invention, a manufacturing method of a semiconductor device comprises:

(a) pressing a first semiconductor chip having a first surface on which first electrodes are formed to a substrate having an interconnecting pattern with a first adhesive which is located between the first surface and the substrate, and connecting the first electrodes to the interconnecting pattern electrically, and forming a first adhesive section which is made of the first adhesive on a side surface of the first semiconductor chip;

(b) pressing a second semiconductor chip having a second surface on which second electrodes are formed to a substrate having an interconnecting pattern with a second adhesive which is located between the second surface and the substrate, and connecting the second electrodes to the interconnecting pattern electrically, and forming a second adhesive section which is made of the second adhesive on a side surface of the second semiconductor chip; and

(c) grinding the first semiconductor chip, the second semiconductor chip, the first adhesive section, and the second adhesive section simultaneously from a surface of the first semiconductor chip opposite to the first surface.

According to the third aspect of the present invention, a semiconductor device is manufactured by using the above-described manufacturing method.

According to the fourth aspect of the present invention, a semiconductor device comprises:

a substrate on which an interconnecting pattern is formed;

a semiconductor chip having a first surface which faces the substrate and a second surface opposite to the first surface;

an electrode which electrically connects the semiconductor chip with the interconnecting pattern and is formed on the first surface; and

a covering section which covers a side surface of the semiconductor chip and is made of an adhesive, the covering section having upper surface, the upper surface and the second surface being substantially coplanar.

According to the fifth aspect of the present invention a semiconductor device comprises:

a substrate on which an interconnecting pattern is formed;

a semiconductor chip having a first surface which faces the substrate;

an electrode which electrically connects the semiconductor chip with the interconnecting pattern and is formed on the first surface; and

a covering section which covers a side surface of the semiconductor chip,

wherein the covering section is formed by grinding an adhesive section, which is made of an adhesive, as well as the semiconductor chip from the second surface of the semiconductor chip opposite to the first surface, after forming the adhesive section on a side surface of the semiconductor chip by pressing the semiconductor chip against the substrate through the adhesive with the first surface facing the substrate.

A circuit board according to the sixth aspect of the present invention is equipped with one of the above-described semiconductor devices.

Electronic equipment according to the seventh aspect of the present invention comprises one of the above-described semiconductor devices.

### BRIEF DESCRIPTION OF THE SEVERAL VIEWS OF THE DRAWING

FIGS. 1A and 1B are views showing a method of manufacturing a semiconductor device according to an embodiment to which the present invention is applied.

FIG. 2 is a view showing the method of manufacturing a semiconductor device according to the embodiment to which the present invention is applied.

FIG. 3 is a view showing a semiconductor device according to an embodiment to which the present invention is applied.

FIG. 4 is a view for describing a method of manufacturing a semiconductor device according to a modification example of the embodiment to which the present invention is applied.

FIG. 5 is a view showing a circuit board equipped with the semiconductor device according to the embodiment to which the present invention is applied.

FIG. 6 is a view showing electronic equipment including the semiconductor device according to the embodiment to which the present invention is applied.

FIG. 7 is a view showing electronic equipment including the semiconductor device according to the embodiment to which the present invention is applied.

### DETAILED DESCRIPTION OF THE EMBODIMENT

Embodiments of the present invention may provide a semiconductor device excelling in handling capability and capable of achieving a decrease in size and an increase in the degree of integration and a method of manufacturing the same, a circuit board, and electronic equipment.

(1) A method of manufacturing a semiconductor device according to one embodiment comprises:

(a) pressing a semiconductor chip having a first surface on which electrodes are formed to a substrate having an interconnecting pattern with an adhesive which is located between the first surface and the substrate, and connecting the electrodes to the interconnecting pattern electrically, and forming an adhesive section which is made of the adhesive on a side surface of the semiconductor chip; and

(b) grinding the semiconductor chip and the adhesive section simultaneously from a second surface of the semiconductor chip opposite to the first surface.

According to this configuration, the semiconductor chip is thinly ground on the substrate after securing the semiconductor chip to the substrate. Therefore, the semiconductor chip having a sufficient thickness before being thinly ground is handled when mounting the semiconductor chip on the substrate. As a result, the semiconductor chip does not crack when mounting. Moreover, since the semiconductor chip before grinding is pressed against the substrate, the semiconductor chip can be prevented from warping.

(2) In this manufacturing method, the adhesive may be an anisotropic conductive material in which conductive fillers are dispersed.

(3) A method of manufacturing a semiconductor device according to another embodiment comprises:

(a) pressing a first semiconductor chip having a first surface on which first electrodes are formed to a substrate having an interconnecting pattern with a first adhesive which is located between the first surface and the substrate, and connecting the first electrodes to the interconnecting pattern electrically, and forming a first adhesive section which is made of the first adhesive on a side surface of the first semiconductor chip;

(b) pressing a second semiconductor chip having a second surface on which second electrodes are formed to a substrate having an interconnecting pattern with a second adhesive which is located between the second surface and the substrate, and connecting the second electrodes to the interconnecting pattern electrically, and forming a second adhesive section which is made of the second adhesive on a side surface of the second semiconductor chip; and

(c) grinding the first semiconductor chip, the second semiconductor chip, the first adhesive section, and the second adhesive section simultaneously from a surface of the first semiconductor chip opposite to the first surface.

According to this configuration, the semiconductor chips are thinly ground on the substrate after securing the first and second semiconductor chips to the substrate. Therefore, the first and second semiconductor chips having a sufficient thickness before being thinly ground are handled when mounting the semiconductor chips on the substrate. As a result, the first and second semiconductor chips do not crack when mounting. Moreover, since the first and second semiconductor chips before grinding are pressed against the substrate, the semiconductor chips can be prevented from warping. Furthermore, since a plurality of semiconductor chips can be ground simultaneously, productivity is increased.

(4) In this manufacturing method, the first adhesive which bonds the first semiconductor chip, and the second adhesive which bonds the second semiconductor chip may be integrally provided on the substrate before the step (a).

(5) A semiconductor device according to further embodiment is manufactured by using the above-described manufacturing method.

(6) A semiconductor device according to still another embodiment comprises:

a substrate on which an interconnecting pattern is formed;

a semiconductor chip having a first surface which faces the substrate and a second surface opposite to the first surface;

an electrode which electrically connects the semiconductor chip with the interconnecting pattern and is formed on the first surface; and

a covering section which covers a side surface of the semiconductor chip and is made of an adhesive, the covering section having upper surface, the upper surface and the second surface being substantially coplanar.

According to this configuration, the covering section is provided on a side of the semiconductor chip so as to be level with the upper surface of the semiconductor chip. Specifically, the thickness from the upper surface of the substrate to the upper surface of the covering section is substantially equal to the thickness from the upper surface of the substrate to the upper surface of the semiconductor chip. The thickness from the upper surface of the substrate to the upper surface of the semiconductor chip used herein refers to the distance from the upper surface of the substrate to the upper surface of the semiconductor chip in the area in which the side of the semiconductor chip is in contact with the covering section. The thickness from the upper surface of the substrate to the upper surface of the covering section used herein refers to the distance from the upper surface of the substrate to the upper surface of the covering section in the area in which the side of the semiconductor chip is in contact with the covering section.

This prevents moisture, minute refuse, and the like from entering the semiconductor device. In the case where the covering section is formed of an adhesive, for example, the thickness of the semiconductor device can be decreased by providing the adhesive in a region including the side of the semiconductor chip and grinding the semiconductor chip and the adhesive simultaneously, while maintaining tolerance to load applied to the semiconductor device (mechanical strength) at a high level. Specifically, since the area in which the semiconductor chip is in contact with the adhesive can be increased by covering the entire surface of the side of the semiconductor chip, tolerance of the semiconductor chip to an impact and the like applied to the semiconductor device can be increased. This enables the semiconductor chip to be effectively secured to the substrate without providing the adhesive on the upper surface of the semiconductor device, whereby the thickness of the semiconductor device can be decreased.

(7) A semiconductor device according to still further embodiment comprises:

a substrate on which an interconnecting pattern is formed;

a semiconductor chip having a first surface which faces the substrate;

an electrode which electrically connects the semiconductor chip with the interconnecting pattern and is formed on the first surface; and

a covering section which covers a side surface of the semiconductor chip,

wherein the covering section is formed by grinding an adhesive section, which is made of an adhesive, as well as the semiconductor chip from the second surface of the semiconductor chip opposite to the first surface, after forming the adhesive section on a side surface of the semiconductor chip by pressing the semiconductor chip against the substrate through the adhesive with the first surface facing the substrate.

According to this configuration, moisture, minute refuse, and the like can be prevented from entering the semiconductor device. Moreover, the thickness of the semiconductor device can be decreased by providing the adhesive section on the side of the semiconductor chip and grinding the semiconductor chip and the adhesive section simultaneously, while maintaining tolerance to load applied to the semiconductor device (mechanical strength) at a high level. Specifically, since the area in which the semiconductor chip is in contact with the adhesive can be increased by covering the entire surface of the side of the semiconductor chip, tolerance of the semiconductor chip to impact and the like applied to the semiconductor device can be increased. This enables the semiconductor chip to be effectively secured to the substrate without providing the adhesive on the upper surface of the semiconductor device, whereby the thickness of the semiconductor device can be decreased.

(8) In this semiconductor device, the adhesive may be an anisotropic conductive material in which conductive fillers are dispersed.

(9) A circuit board according to yet another embodiment is equipped with any one of the above-described semiconductor devices.

(10) Electronic equipment according to yet further embodiment comprises any one of the above-described semiconductor devices.

Embodiments of the present invention are described below with reference to the drawings. However, the present invention is not limited to the embodiments given below.

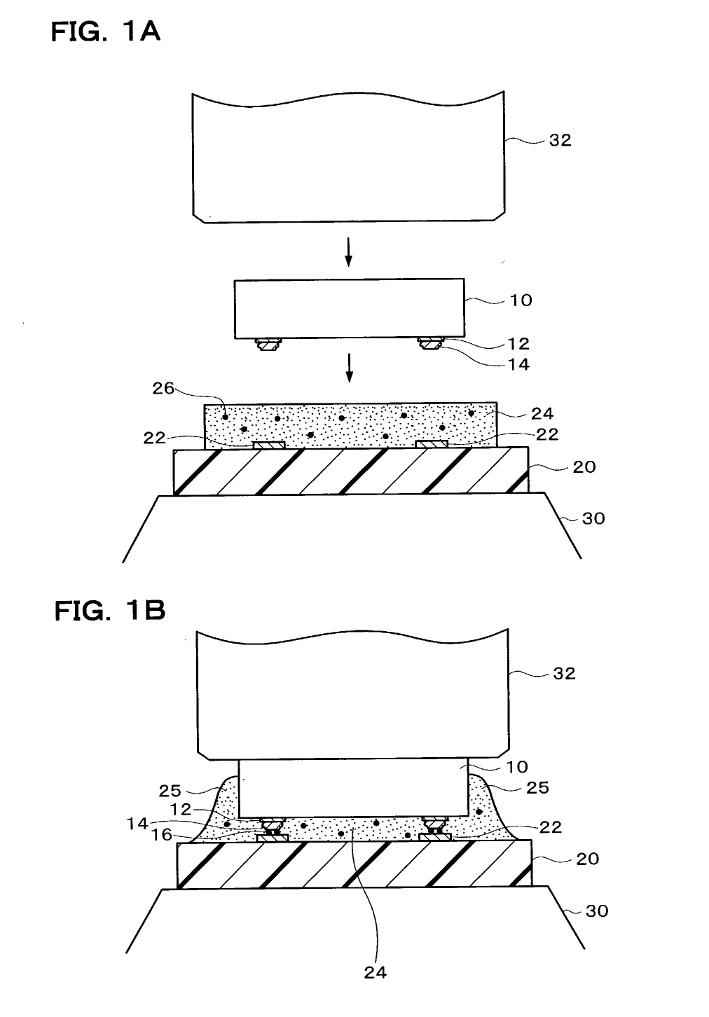

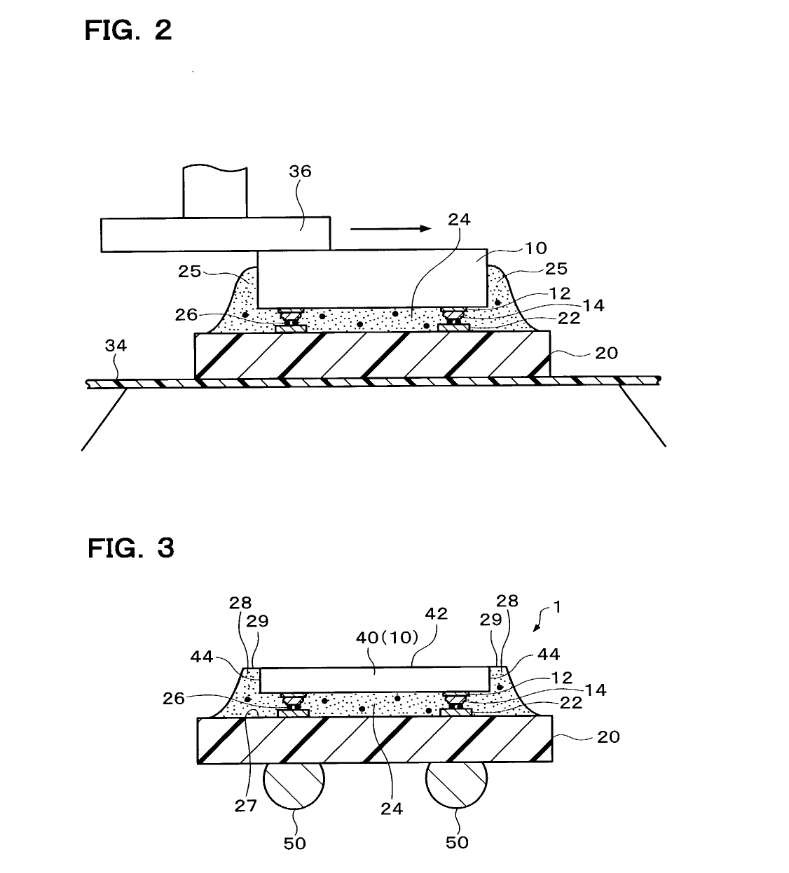

FIGS. 1A to 2 are views showing a method of manufacturing a semiconductor device according to the present embodiment. FIG. 3 is a view showing the semiconductor device according to the present embodiment. In the present embodiment, a semiconductor chip 10 and a substrate 20 are provided.

The semiconductor chip 10 is generally in the shape of a rectangular parallelepiped. However, the shape of the semiconductor chip 10 is not limited thereto. The shape of the semiconductor chip 10 is determined when cutting a semiconductor wafer. A plurality of pads 12 (electrodes) is formed on the semiconductor chip 10. The pads 12 are external electrodes of a circuit element formed on the semiconductor chip 10 and thinly formed of aluminum, copper, or the like. The plurality of pads 12 is formed on the semiconductor chip 10 on the side on which the circuit element is formed. In more detail, the pads 12 are generally formed on the ends (ends along two opposing sides, for example) of the side of the semiconductor chip 10.

A bump 14 is generally formed on each pad 12. The bump 14 is formed by using a ball bump method, an electroplating method, an electroless plating method, or the like. The semiconductor chip 10 and the substrate 20 are electrically connected by forming the bump 14 in the shape of a projection on the pad 12. A passivation film (not shown) is generally formed on the semiconductor chip 10 to avoid at least part of the pads 12.

The substrate 20 may be formed of either an organic material or an inorganic material. The substrate 20 may be formed of a composite structure of an organic material and an inorganic material. As an example of the substrate 20 formed of an organic material, a flexible substrate formed of a polyimide resin can be given. As examples of the substrate 20 formed of an inorganic material, a ceramic substrate and a glass substrate can be given. As an example of the substrate 20 formed of a composite structure of an organic material and an inorganic material, a glass epoxy substrate can be given. A multilayer substrate or a built-up substrate may be used as the substrate 20.

An interconnecting pattern 22 is formed on the substrate 20. The interconnecting pattern 22 is formed by wiring a plurality of interconnects in a specific shape. Some of the plurality of interconnects have an electrical connection section (land, for example) which is electrically connected with the bump 14.

A step of securing the semiconductor chip 10 to the substrate 20 is described below with reference to FIGS. 1A and 1B. In more detail, the semiconductor chip 10 is secured to the substrate 20 by using an adhesive 24.

As shown in FIG. 1A, the substrate 20 is disposed on a stage 30. The adhesive 24 is provided on the substrate 20. The adhesive 24 exhibits adhesion by application of specific energy (heat or light, for example). In the case where the adhesive 24 exhibits adhesion by application of thermal energy, a thermosetting resin or a thermoplastic resin may be used as the adhesive 24. The adhesive 24 may be provided on the substrate 20 as shown in FIG. 1A or provided on the semiconductor chip 10.

As shown in FIG. 1A, the semiconductor chip 10 is disposed so that the side on which the pads 12 (bumps 14) are formed faces the substrate 20. Specifically, the side of the semiconductor chip 10 opposite to the side on which the pads 12 are formed is pressed in the direction toward the substrate 20 by using a tool 32.

In the present embodiment, the semiconductor chip 10 is secured to the substrate 20 and the bumps 14 and the interconnecting pattern 22 are electrically connected by pressing the semiconductor chip 10 against the substrate 20. The semiconductor chip 10 may be secured to the substrate 20 by pressing the semiconductor chip 10 against the substrate 20 to such an extent that the bumps 14 and the interconnecting pattern 22 are not electrically connected. In this case, the bump 14 and the interconnecting pattern 22 are electrically connected by pressing a semiconductor chip 40 (see FIG. 3) against the substrate 20 after performing a grinding step described later.

In the present embodiment, an anisotropic conductive material is used as the adhesive 24. The anisotropic conductive material is prepared by dispersing conductive fillers 26 in an insulating adhesive (binder). A dispersing agent (silica-type fillers, for example) maybe added to the anisotropic conductive material. A thermosetting resin is generally used as the binder. The anisotropic conductive material may be an anisotropic conductive film in the shape of a sheet or an anisotropic conductive paste. The conductive fillers 26 are crushed between the bumps 14 of the semiconductor chip 10 and the interconnecting pattern 22 of the substrate 20, whereby the bumps 14 and the interconnecting pattern 22 are electrically connected.

As shown in FIG. 1B, the semiconductor chip 10 is pressed in the direction toward the substrate 20 by lowering the tool 32 toward the semiconductor chip 10. For example, the semiconductor chip 10 is pressed by using the tool 32 for about 10 to 20 seconds. In the case where the adhesive 24 exhibits adhesion by application of thermal energy, the semiconductor chip 10 is heated during pressing. The semiconductor chip 10 may be heated by the tool 32, or the substrate 20 may be heated by the stage 30.

Part of the adhesive 24 is discharged outside the semiconductor chip 10 by pressing the semiconductor chip 10 against the substrate 20. As a result, an adhesive section 25 consisting of part of the adhesive 24 is formed on the side of the semiconductor chip 10. In the present embodiment, since the semiconductor chip 10 is comparatively thick (thickness of about 600 to 700 μm, for example), the adhesive section 25 is generally formed at a position lower than the pressed side (side opposite to the substrate 20) of the semiconductor chip 10 in the press step. Therefore, the adhesive 24 (adhesive section 25) rarely adheres to the tool 32 in the press step. Specifically, it is unnecessary to interpose a sheet for preventing the adhesive 24 (adhesive section 25) from adhering (fluororesin sheet, for example) between the tool 32 and the semiconductor chip 10 in the press step. Therefore, since the pressing force of the tool 32 is not absorbed by the sheet, the pressing force of the tool 32 can be securely transmitted to the semiconductor chip 10. The adhesive section 25 may be provided at a position higher than the pressed side of the semiconductor chip 10. In this case, the semiconductor chip 10 can be reliably secured to the substrate 20. The height of the adhesive section 25 before grinding is higher than the height of the semiconductor chip 40 (see FIG. 3) after grinding.

The semiconductor chip 10 can be secured to the substrate 20 in this manner. In the present embodiment, since the adhesive 24 is also provided on the side of the semiconductor chip 10, the semiconductor chip 10 can be secured to the substrate 20 more reliably. In the present embodiment, the semiconductor chip 10 may further be secured to the substrate 20 by using an adhesive such as a resin, resin sealing, or the like.

As shown in FIG. 2, the semiconductor chip 10 secured to the substrate 20 is ground. In more detail, the semiconductor chip 10 is ground on the side opposite to the substrate 20 (side opposite to the active surface). The adhesive section 25 provided on the side of the semiconductor chip 10 is also ground. For example, the substrate 20 may be held on the stage by attaching the substrate 20 to a tape (UV tape, for example) 34, and the semiconductor chip 10 and the adhesive section 25 may be ground by using grindstone provided on a grinding tool 36 or the like. In this case, even if stress in the horizontal direction (direction parallel to the side of the substrate 20) is applied to the semiconductor chip 10 by grinding, the semiconductor chip 10 can be prevented from being removed from the substrate 20 by allowing the adhesive section 25 to suitably absorb the stress.

Grinding swarf is produced by grinding. In the present embodiment, since the semiconductor chip 10 is ground after mounting the semiconductor chip 10 on the substrate 20, grinding swarf can be prevented from entering the electrical connection section (connection section between the bumps 14 and the interconnecting pattern 22) between the semiconductor chip 10 and the substrate 20. Therefore, occurrence of electrical connection failure of the semiconductor device can be prevented.

A thin semiconductor device 1 shown in FIG. 3 is manufactured in this manner. The semiconductor device according to the present embodiment includes the semiconductor chip 40 and the substrate 20. The semiconductor device according to the present embodiment includes a configuration derived from the above method of manufacturing a semiconductor device. The semiconductor chip 40 is formed by thinly grinding the semiconductor chip 10. The thickness of the semiconductor chip 40 may be about 50 μm, for example. The semiconductor chip 40 has an upper surface 42 and a side 44. The semiconductor chip 40 is bonded to the substrate 20 on the side (lower side) opposite to the upper surface 42 by the adhesive 24.

The adhesive 24 has a covering section 28 formed on the side of the semiconductor chip 40. The covering section 28 on the side 44 of the semiconductor chip 40 has a section which is level with the upper surface 42 of the semiconductor chip 40. In other words, the upper surface of the semiconductor device 1 is formed flat by the upper surface 42 of the semiconductor chip 40 and an upper surface 29 of the covering section 28. Specifically, the thickness from an upper surface 27 of the substrate 20 to the upper surface 42 of the semiconductor chip 40 is equal to the thickness from the upper surface 27 of the substrate 20 to the upper surface 29 of the covering section 28. The thickness from the upper surface 27 of the substrate 20 to the upper surface 42 of the semiconductor chip 40 used herein refers to the distance from the upper surface 27 of the substrate 20 to the upper surface 42 of the semiconductor chip 40 in the area in which the side 44 of the semiconductor chip 40 is in contact with the covering section 28. The thickness from the upper surface 27 of the substrate 20 to the upper surface 29 of the covering section 28 used herein refers to the distance from the upper surface 27 of the substrate 20 to the upper surface 29 of the covering section 28 in the area in which the side 44 of the semiconductor chip 40 is in contact with the covering section 28. In other words, the adhesive 24 is provided in contact with each side of the semiconductor chip 40 excluding the upper surface 42.

Since the covering section 28 is provided on the side 44 of the semiconductor chip 40 so as to be level with the upper surface of the semiconductor chip 40, moisture resistance of the semiconductor device can be improved. Specifically, moisture, minute refuse, and the like can be prevented from entering the semiconductor device as far as possible. The thickness of the semiconductor device can be decreased by providing the adhesive 24 (adhesive section 25) on the side 44 of the semiconductor chip 40 and grinding the semiconductor chip 10 and the adhesive 24 (adhesive section 25) at the same time, while maintaining tolerance to load applied to the semiconductor device (mechanical strength) at a high level. Specifically, since the area in which the adhesive 24 adheres to the semiconductor chip 40 can be increased by covering the entire surface of the side 44 of the semiconductor chip 40, tolerance of the semiconductor chip 40 to impact and the like applied to the semiconductor device can be increased. This enables the semiconductor chip 40 to be effectively secured to the substrate 20 without providing the adhesive 24 on the upper surface 42 of the semiconductor device, whereby the thickness of the semiconductor device can be decreased.

In the example shown in FIG. 3, the semiconductor device 1 further includes external terminals 50. The external terminals 50 are electrically connected with the interconnecting pattern 22 through through-holes (not shown) and provided on the substrate 20 on the side opposite to the semiconductor chip 10. The external terminals 50 may be solder balls. The external terminals 50 may be formed by printing solder and performing a reflow step.

According to the semiconductor device of the present embodiment, a thin semiconductor device with a high degree of integration can be provided by using a manufacturing method excelling in handling capability.

### Modification Example

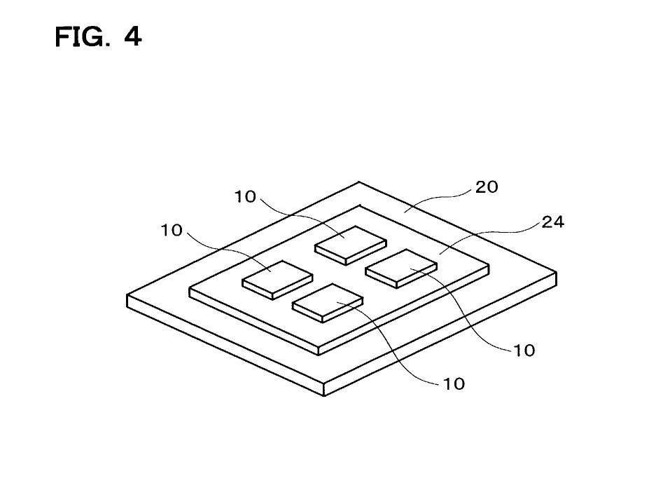

FIG. 4 is a view for describing a method of manufacturing a semiconductor device according to a modification example of the present embodiment. In this modification example, a plurality of semiconductor chips 10 is secured to one substrate 20, and the plurality of semiconductor chips 10 is ground at the same time.

The substrate 20 has a plurality of regions for mounting the semiconductor chips 10. The plurality of regions for mounting the semiconductor chips 10 on the substrate 20 may be arranged in a matrix.

The adhesive 24 may be integrally provided over the plurality of regions for mounting the semiconductor chips 10 on the substrate 20. This enables the adhesive 24 to be easily provided. In the example shown in FIG. 4, the adhesive 24 in the shape of a sheet (film) is provided.

After securing the plurality of semiconductor chips 10 to the substrate 20, the plurality of semiconductor chips 10 is ground at the same time. In more detail, the plurality of semiconductor chips 10 is ground on the side opposite to the substrate 20 together with the adhesive 24 (adhesive section). In this case, all the semiconductor chips 10 on the substrate 20 may be ground at the same time, or at least two semiconductor chips 10 may be ground at the same time. This enables the thickness of the plurality of semiconductor chips 10 to be decreased at the same time, whereby productivity is increased. Moreover, since the plurality of semiconductor chips 10 is arranged on the substrate 20 with which the semiconductor chips 10 are electrically connected, it is unnecessary to rearrange the semiconductor chips 10 for grinding.

The substrate 20 is cut for each semiconductor chip 10, whereby the semiconductor devices 1 are manufactured. According to this modification example, a manufacturing method excelling in productivity can be provided while achieving the above-described effects.

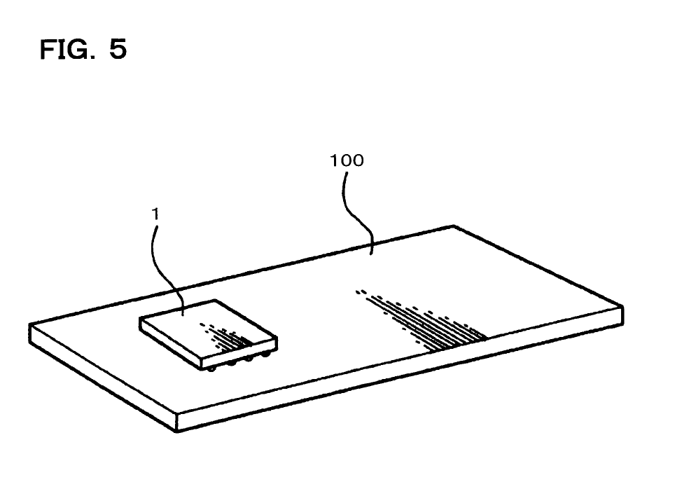

FIG. 5 is a view showing a circuit board 100 equipped with the semiconductor device according to the present embodiment (including the modification example). As the circuit board 100, an organic substrate such as a glass epoxy substrate is generally used. An interconnecting pattern is formed of copper or the like on the circuit board 100 so that a desired circuit is formed. The interconnecting pattern and the external terminals of the semiconductor device are electrically connected by mechanically connecting the interconnecting pattern with the external terminals.

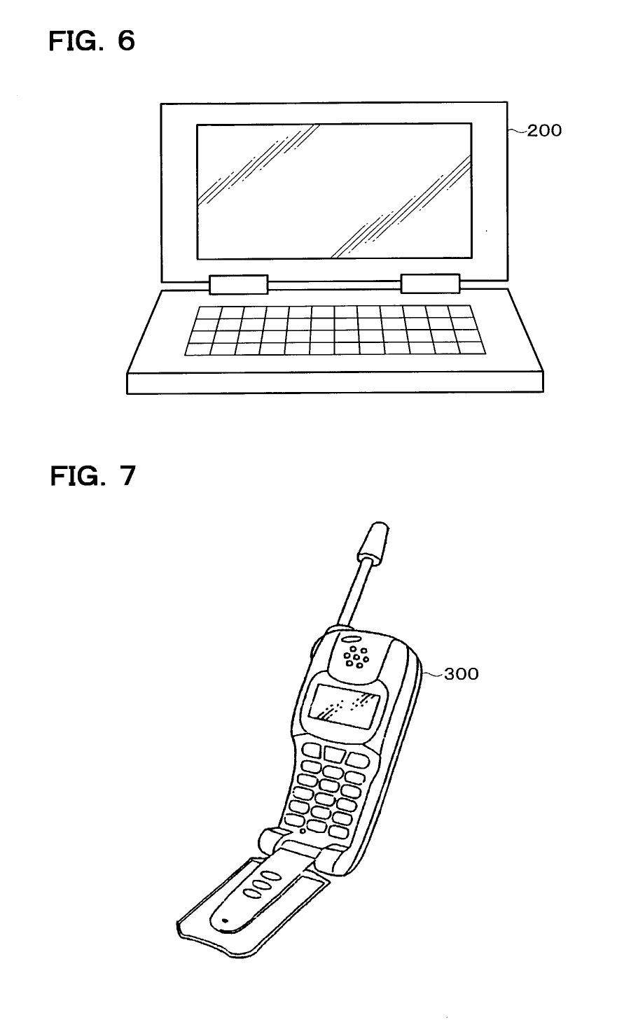

FIGS. 6 and 7 respectively show a notebook-type personal computer 200 and a portable telephone as examples of electronic equipment including the semiconductor device to which the present invention is applied.

What is claimed is:

1. A manufacturing method of a semiconductor device comprising:
(a) pressing a semiconductor chip including a first surface on which electrodes are formed to a substrate including an interconnecting pattern with an adhesive which is located between the first surface and the substrate, and connecting the electrodes to the interconnecting pattern electrically, and forming an adhesive section which is made of the adhesive on a side surface of the semiconductor chip; and
(b) grinding the semiconductor chip and the adhesive section simultaneously from a second surface of the semiconductor chip opposite to the first surface.

2. The manufacturing method as defined in claim 1, wherein the adhesive is an anisotropic conductive material in which conductive fillers are dispersed.

3. A manufacturing method of a semiconductor device comprising:
(a) pressing a first semiconductor chip including a first surface on which first electrodes are formed to a substrate including an interconnecting pattern with a first adhesive which is located between the first surface and the substrate, and connecting the first electrodes to the interconnecting pattern electrically, and forming a first adhesive section which is made of the first adhesive on a side surface of the first semiconductor chip;
(b) pressing a second semiconductor chip including a second surface on which second electrodes are formed to a substrate including an interconnecting pattern with a second adhesive which is located between the second surface and the substrate, and connecting the second electrodes to the interconnecting pattern electrically, and forming a second adhesive section which is made of the second adhesive on a side surface of the second semiconductor chip; and
(c) grinding the first semiconductor chip, the second semiconductor chip, the first adhesive section, and the second adhesive section simultaneously from a surface of the first semiconductor chip opposite to the first surface.

4. The manufacturing method as defined in claim 3,
wherein the first adhesive and the second adhesive are anisotropic conductive materials in which conductive fillers are dispersed.

5. The manufacturing method as defined in claim 3,
wherein the first adhesive which bonds the first semiconductor chip, and the second adhesive which bonds the second semiconductor chip are integrally provided on the substrate before the step (a).

6. A semiconductor device manufactured by the manufacturing method as defined in claim 1.

7. A semiconductor device manufactured by the manufacturing method as defined in claim 3.

8. A semiconductor device comprising:
a substrate on which an interconnecting pattern is formed;
a semiconductor chip including a first surface which faces the substrate and a second surface opposite to the first surface;
an electrode which electrically connects the semiconductor chip with the interconnecting pattern and is formed on the first surface; and
a covering section which covers a side surface of the semiconductor chip and is made of an adhesive, the covering section including upper surface, the upper surface and the second surface being substantially coplanar.

9. A semiconductor device comprising:
a substrate on which an interconnecting pattern is formed;
a semiconductor chip including a first surface which faces the substrate;
an electrode which electrically connects the semiconductor chip with the interconnecting pattern and is formed on the first surface; and
a covering section which covers a side surface of the semiconductor chip,
wherein the covering section is formed by grinding an adhesive section, which is made of an adhesive, as well as the semiconductor chip from the second surface of the semiconductor chip opposite to the first surface, after forming the adhesive section on a side surface of the semiconductor chip by pressing the semiconductor chip against the substrate through the adhesive with the first surface facing the substrate.

10. The semiconductor device as defined in claim 8,
wherein the adhesive is an anisotropic conductive material in which conductive fillers are dispersed.

11. The semiconductor device as defined in claim 9,
wherein the adhesive is an anisotropic conductive material in which conductive fillers are dispersed.

12. A circuit board equipped with the semiconductor device as defined in claim 8.

13. A circuit board equipped with the semiconductor device as defined in claim 9.

14. Electronic equipment comprising the semiconductor device as defined in claim 8.

15. Electronic equipment comprising the semiconductor device as defined in claim 9.
